(19) United States
(12) Patent Application Publication
(10) Pub. No.: US 2026/0082674 A1
(43) Pub. Date: Mar. 19, 2026

(54) FABRICATION METHOD FOR INTEGRATED STRUCTURE OF TRANSISTORS WITH DIFFERENT OPERATING VOLTAGES

(71) Applicant: Shanghai Huali Integrated Circuit Corporation, Shanghai (CN)

(72) Inventors: Qiwei Wang, Shanghai (CN); Jiamin Zhou, Shanghai (CN); Zhen Gu, Shanghai (CN); Lei Zhang, Shanghai (CN); Haoyu Chen, Shanghai (CN)

(73) Assignee: Shanghai Huali Integrated Circuit Corporation, Shanghai (CN)

(21) Appl. No.: 19/214,129

(22) Filed: May 21, 2025

(30) Foreign Application Priority Data
Sep. 14, 2024 (CN) 202411296504.2

(51) Int. Cl. H10D 84/01; H01L 21/033; H01L 21/28; H01L 21/762

(52) U.S. Cl. CPC H10D 84/0144; H10D 64/01346; H10D 84/0151; H10P 76/4085; H10W 10/014; H10W 10/17

(57) ABSTRACT

The present application discloses a fabrication method for an integrated structure of transistors with different operating voltages. A high-voltage transistor area and a low-voltage transistor area are protected by a retained hard mask layer before a medium-voltage gate oxide layer is grown, so as to avoid additional growth of gate oxide layers above active areas of the high-voltage transistor area and the low-voltage transistor area, thereby avoiding the deterioration of a step height of the low-voltage transistor area due to the subsequent use of a large amount of acid to remove the gate oxide layer additionally grown above the active area of the low-voltage transistor area, and preventing the electrical property and the reliability of a low-voltage device from being subsequently influenced while avoiding the influence of the etching with the large amount of acid on the thickness of a high-voltage gate oxide layer which has already been grown.

### CROSS-REFERENCE TO RELATED APPLICATIONS

This application claims priority to Chinese patent application No. 202411296504.2, filed on Sep. 14, 2024, the disclosure of which is incorporated herein by reference in its entirety.

### TECHNICAL FIELD

The present application relates to semiconductor fabrication technology, and in particular, to a fabrication method for an integrated structure of transistors with different operating voltages.

### BACKGROUND

A high-voltage integrated circuit is widely popular in the mature process chip foundry market due to wide product application market and high product profit, and therefore various chip foundries have developed their own high-voltage integrated circuit process platforms on their own mature process platforms. At present, a HV (high-voltage) platform for a 28 nm process generally includes a low-voltage (0.9V or so) device for a SRAM circuit, a medium-voltage (8V or so) device for a source driver circuit, and a high-voltage (for example, 32V or so or 25V or so) device for a gate driver circuit. Thicknesses of gate oxide layers corresponding to devices with different driving voltages vary greatly, and in actual production, the devices are generally fabricated in an order of gate oxide thickness from thick to thin. Since the gate oxide thickness of the medium-voltage device is typically several hundred angstroms, a large amount of acid is required to remove gate oxide by using an existing solution. On the one hand, the use of the large amount of acid easily leads to over-etching of a shallow trench isolation (STI) oxide used as channel isolation for the low-voltage device, resulting in slightly higher step height of the low-voltage device, which subsequently affects the electrical property and the reliability of the low-voltage device. On the other hand, the etching with the large amount of acid affects the thickness of a high-voltage gate oxide layer has already been grown, easily resulting in larger fluctuations in a high-voltage gate oxide thickness between different batches of products, which is not conducive to the precise control of a process. Therefore, for the fabrication of a medium-voltage gate oxide layer, it is particularly noted that, in order to reduce the influence of the fabrication process on other areas, when a medium-voltage gate oxide fabrication solution is designed, a thickness of a gate oxide layer of the high-voltage device and a step height of the low-voltage device on which gate oxide is to be grown are need protected.

An existing fabrication method for a gate oxide layer of the medium-voltage device inside a high-voltage integrated circuit is to firstly grow a high-voltage area gate oxide layer in a thermal oxidation manner, then perform well ion injection, and then fabricate the medium-voltage gate oxide layer of the medium-voltage device. A fabrication process of medium-voltage gate oxide includes the following steps: firstly, opening a medium-voltage transistor area by photoresist, and downwards etching a silicon substrate, so as to ensure that the surface of the wafer is flat after the subsequent deposition of the medium-voltage gate oxide layer; then growing a medium-voltage gate oxide layer in a manner of first an ISSG (In-Situ Steam Generation) process and then an HTO (High Temperature Oxidation) process, and growing a gate oxide layer required by the medium-voltage device on the surface of the whole wafer; and finally, protecting a gate oxide area of the medium-voltage device by the photoresist, and removing the gate oxide layer simultaneously grown on other areas in the process by wet etching. As the gate oxide thickness of the medium-voltage device is typically several hundred angstroms, the large amount of acid is required to remove the gate oxide by using the existing solution. On the one hand, oxide (STI) used as channel isolation for the low-voltage device is over-etched, such that the step height of the low-voltage device is slightly higher, as shown in FIG. 1, which subsequently affects the electrical property and the reliability of the low-voltage device. On the other hand, etching with the large amount of acid affects the thickness of the high-voltage gate oxide layer, easily resulting in larger fluctuations in the high-voltage gate oxide thickness between different batches of products, which is not conducive to accurate control of the process.

### BRIEF SUMMARY

A technical problem to be solved by the present application is to provide a fabrication method for an integrated structure of transistors with different operating voltages, so as to avoid the deterioration of a step height of a low-voltage transistor area due to the subsequent use of a large amount of acid to remove a gate oxide layer additionally grown above an active area of the low-voltage transistor area, and prevent the electrical property and the reliability of a low-voltage device from being subsequently influenced while avoiding the influence of the etching with the large amount of acid on the thickness of a high-voltage gate oxide layer which has already been grown.

In order to solve the technical problem mentioned above, the present application provides a fabrication method for an integrated structure of transistors with different operating voltages. The integrated structure has a high-voltage transistor, a medium-voltage transistor and a low-voltage transistor formed on the same silicon substrate 100. The fabrication method includes the following steps:
S1. providing a semiconductor substrate, wherein the semiconductor substrate is a silicon substrate 100 provided with a high-voltage transistor area, a medium-voltage transistor area and a low-voltage transistor area separated by an area shallow trench isolation 101; the high-voltage transistor area is provided with a high-voltage shallow trench isolation 104 inside; the low-voltage transistor area is provided with a low-voltage shallow trench isolation 102 inside; the high-voltage shallow trench isolation 104 is flush or higher than an upper surface of the silicon substrate 100; and an operating voltage of the high-voltage transistor is greater than that of the medium-voltage transistor, and the operating voltage of the medium-voltage transistor is greater than that of the low-voltage transistor;
S2. forming a high-voltage gate oxide layer 105 only in the high-voltage transistor area but not forming the high-voltage gate oxide layer 105 in the low-voltage transistor area and the medium-voltage transistor area, wherein a lower portion of the high-voltage gate oxide layer 105 penetrates deeply into the silicon substrate 100, and an upper surface of the high-voltage gate oxide layer 105 is flush with that of the area shallow trench isolation 101;
S3. depositing a hard mask layer 106 on a surface of a wafer;
S4. coating a first layer of photoresist 107 on the surface of the hard mask layer 106;
S5. developing only the photoresist of the medium-voltage transistor area, and then removing the hard mask layer 106 and a top of the silicon substrate 100 of the medium-voltage transistor area sequentially by dry etching, so as to form a medium-voltage area silicon recess 108 on the top of the silicon substrate 100 of the medium-voltage transistor area;
S6. removing the first layer of photoresist 107 remaining on the surface of the whole wafer, and removing residual byproducts by wet cleaning;
S7. growing a medium-voltage gate oxide layer 109 on the surface of the whole wafer;
S8. coating a second layer of photoresist 110 to the surface of the whole wafer;
S9. developing only the second layer of photoresist 110 of the high-voltage transistor area and the low-voltage transistor area, retaining the second layer of photoresist 110 of the medium-voltage transistor area, and protecting the medium-voltage transistor area with the second layer of photoresist 110;
S10. removing the medium-voltage gate oxide layer 109 of the high-voltage transistor area and the low-voltage transistor area by dry etching, and stopping the dry etching on the hard mask layer 106;
S11. removing the remaining second layer of photoresist 110;
S12. removing the hard mask layer 106 of the high-voltage transistor area and the low-voltage transistor area by wet etching to fabricate the medium-voltage gate oxide layer; and
S13. performing a subsequent process to fabricate an integrated structure of transistors with different operating voltages.

Preferably, in the step S3, the hard mask layer 106 is a SIN layer, and a surface of the SIN layer is oxidized by means of thermal oxygen, and thus a thin oxide layer is generated on the surface of the SIN layer.

Preferably, in the step S12, the wet etching amount of a phosphoric acid solution is adjusted, and the hard mask layer 106 of the high-voltage transistor area and the low-voltage transistor area is removed by wet etching.

Preferably, the high-voltage transistor has an operating voltage of 20V to 35V;
the medium-voltage transistor has an operating voltage of 6V to 10V; and
the low-voltage transistor has an operating voltage of less than 1V.

Preferably, the high-voltage transistor has an operating voltage of 32V or 25V;
the medium-voltage transistor has an operating voltage of 8V; and
the low-voltage transistor has an operating voltage of 0.9V.

Preferably, the silicon substrate 100 of the high-voltage transistor area is provided with a high-voltage P-well; and
the silicon substrate 100 of the medium-voltage transistor area is provided with a medium-voltage P-well.

Preferably, an upper surface of the area shallow trench isolation 101 is higher than that of the silicon substrate 100 by 10 Å to 100 Å.

Preferably, the area shallow trench isolation 101 and the low-voltage shallow trench isolation 102 are silicon oxide; and
the high-voltage gate oxide layer 105 and the medium-voltage gate oxide layer 109 are silicon oxide.

Preferably, in the step S6, the first layer of photoresist 107 remaining on the surface of the whole wafer is removed by dry etching.

Preferably, in the step S1, a liner oxide layer 103 is formed on the upper surface of the silicon substrate 100 of the high-voltage transistor area, the medium-voltage transistor area and the low-voltage transistor area; and
in the step S5, only the photoresist of the medium-voltage transistor area is developed, and then the hard mask layer 106, the liner oxide layer 103 and a top of the silicon substrate 100 of the medium-voltage transistor area are sequentially removed by dry etching, so as to form a medium-voltage area silicon recess 108 on the top of the silicon substrate 100 of the medium-voltage transistor area.

Preferably, the medium-voltage gate oxide layer 109 is grown on the surface of the whole wafer in a manner of first an ISSG process and then an HTO process.

Preferably, in the step S7, the ISSG process has an oxide growth thickness of 40 Å to 120 Å, and the HTO process has an oxide growth thickness of 100 Å to 300 Å.

Preferably, the medium-voltage gate oxide layer 109 grown in the step S7 has a thickness of 100 Å to 350 Å.

Preferably, in the step S5, the formed medium-voltage area silicon recess 108 has a depth of 100 Å to 200 Å in the silicon substrate 100.

Preferably, in the step S2, a depth of a bottom of the high-pressure gate oxide layer 105 penetrating deeply in the silicon substrate 100 ranges from 400 Å to 600 Å.

Preferably, the fabrication method is an integrated process method capable of fabricating an integrated structure of three MOS transistors, that is, a high-voltage MOS transistor, a medium-voltage MOS transistor and a low-voltage MOS transistor, on a 28 HKMG process platform.

According to the fabrication method for the integrated structure of transistors with different operating voltages of the present application, in the process of growing the medium-voltage gate oxide layer, only the photoresist is removed and the hard mask layer is retained after the hard mask layer 106 and the top of the silicone substrate 100 of the medium-voltage transistor area is removed by etching to form the medium-voltage area silicone recess (Si-Recess) 108, and then the medium-voltage gate oxide layer is grown; and then a layer of photoresist is coated to the surface of the wafer, and the high-voltage transistor area and the low-voltage transistor area are opened to remove the medium-voltage gate oxide layer 109 by dry etching and then remove the hard mask layer by wet etching, completing the preparation of the medium-voltage gate oxide layer of the medium-voltage device. In such a fabrication method for the integrated structure of the transistors with different operating voltages, before the medium-voltage gate oxide layer is grown, the high-voltage transistor area and the low-voltage transistor area are protected by the retained hard mask layer, so as to avoid additional growth of the gate oxide layer above the active area of the high-voltage transistor area and the low-voltage transistor area, thereby avoiding the deterioration of the step height of the low-voltage transistor area due to the subsequent use of the large amount of acid to remove the gate oxide layer (for example, a silicon dioxide film layer) additionally grown above the active area of the low-voltage transistor area, and preventing the electrical property and the reliability of the low-voltage device from being subsequently influenced while avoiding the influence of etching with the large amount of acid on the thickness of a high-voltage gate oxide layer which has already been grown, which is conducive to reducing the fluctuation in the process and enhancing the ability to accurately control the process. The fabrication method is simple and controllable, compatible with an existing process, and suitable for mass production.

### BRIEF DESCRIPTION OF THE DRAWINGS

To more clearly illustrate the technical solution of the present application, figures used in the present application will be briefly introduced below. Obviously, the figures in the following description are only some embodiments of the present application, and other figures can be obtained from these figures for those of ordinary skill in the art, without the exercise of inventive effect.

FIG. 1 is a cross-sectional view of a device corresponding to an existing fabrication method for a gate oxide layer of a medium-voltage device inside a high-voltage integrated circuit when a medium-voltage gate oxide layer is formed; and

FIG. 2 through FIG. 12 are cross-sectional views of a structure of a device corresponding to each step of a fabrication method for an integrated structure of transistors with different operating voltages according to an embodiment of the present application.

### DESCRIPTION OF REFERENCE SYMBOLS

100. silicon substrate; 101. area shallow trench isolation; 102. low-voltage shallow trench isolation; 103. liner oxide layer; 104. high-voltage shallow trench isolation; 105. high-voltage gate oxide layer; 106. hard mask layer; 107. first layer of photoresist; 108. medium-voltage area silicon recess; 109. medium-voltage gate oxide layer; and 110. second layer of photoresist.

### DETAILED DESCRIPTION OF THE DISCLOSURE

Technical solutions in embodiments of the present application may be described clearly and completely below in conjunction with figures in the embodiments of the present application. Obviously, the described embodiments are only some of the embodiments of the present application, but not all of the embodiments. The scope of protection of the present application encompasses all other embodiments obtained by those of ordinary skill in the art based on the embodiments of the present application without the exercise of inventive effort.

Terms such as “first”, “second”, etc. in the present application do not indicate any order, number, or importance, but are only to distinguish different constituent parts. The phasing such as “including”, “comprising”, etc. means that an element or object preceded by the phasing encompasses an element or object and equivalents thereof listed below the phasing, but does not exclude other elements or objects. The expression such as “connected”, “coupled”, etc. is not limited to physical or mechanical connections, but may include direct or indirect electrical connections. Terms such as “upper”, “lower”, “left”, “right”, etc. are used only to indicate relative positional relations. When an absolute position of a described object is changed, the relative positional relation may be changed accordingly.

It should be noted that the embodiments of the present application and features in the embodiments may be combined with each other without contradictory.

### Embodiment 1

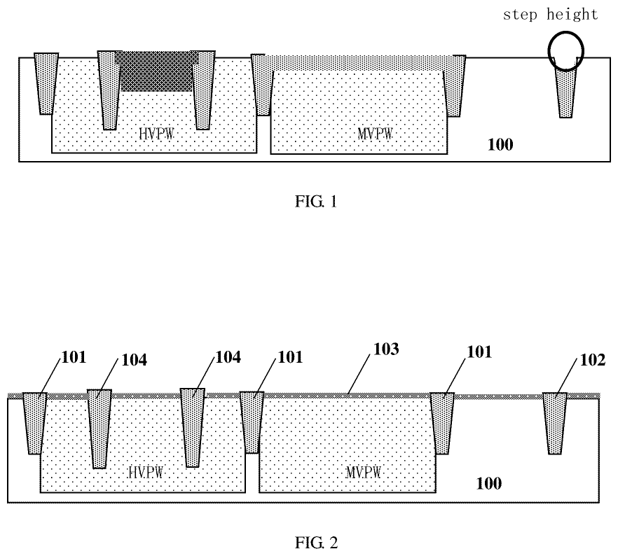

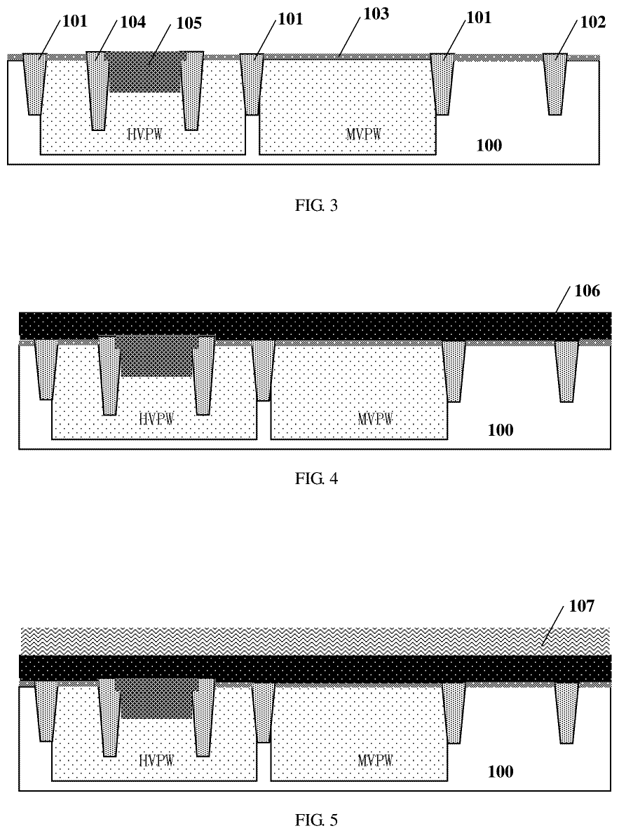

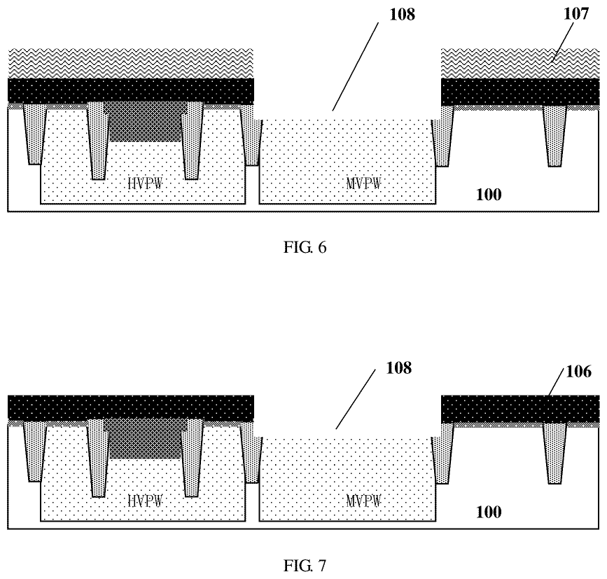

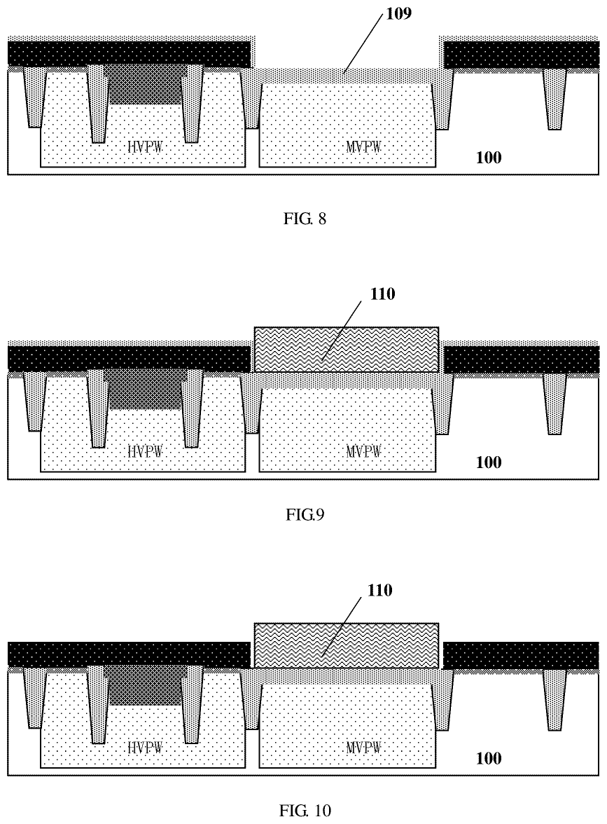

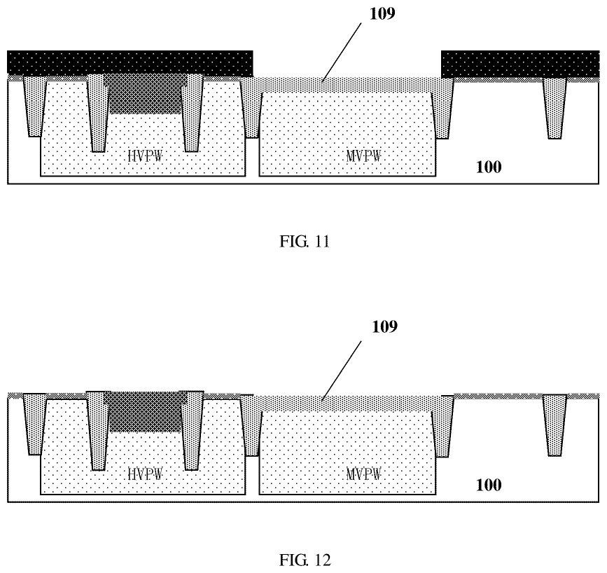

Disclosed is a fabrication method for an integrated structure of transistors with different operating voltages, the integrated structure has a high-voltage transistor, a medium-voltage transistor and a low-voltage transistor formed on the same silicon substrate 100, and the fabrication method includes the following steps:
S1. as shown in FIG. 2, providing a semiconductor substrate, wherein the semiconductor substrate is a silicon substrate 100 provided with a high-voltage transistor area, a medium-voltage transistor area and a low-voltage transistor area separated by an area shallow trench isolation (STI) 101; the high-voltage transistor area is provided with a high-voltage shallow trench isolation (STI) 104 inside; the low-voltage transistor area is provided with a low-voltage shallow trench isolation (STI) 102 inside; the high-voltage shallow trench isolation 104 is flush or slightly higher than an upper surface of the silicon substrate 100; and an operating voltage of the high-voltage transistor is greater than that of the medium-voltage transistor, and the operating voltage of the medium-voltage transistor is greater than that of the low-voltage transistor;
S2. as shown in FIG. 3, forming a high-voltage gate oxide layer 105 only in the high-voltage transistor area but not forming the high-voltage gate oxide layer 105 in the low-voltage transistor area and the medium-voltage transistor area, wherein a lower portion of the high-voltage gate oxide layer 105 penetrates deeply into the silicon substrate 100, and an upper surface of the high-voltage gate oxide layer 105 is flush with that of the area shallow trench isolation 101;
S3. as shown in FIG. 4, depositing a hard mask layer 106 on a surface of wafer;
S4. as shown in FIG. 5, coating a first layer of photoresist 107 on the surface of the hard mask layer 106;
S5. as shown in FIG. 6, developing only the photoresist of the medium-voltage transistor area, and then removing the hard mask layer 106 and a top of the silicon substrate 100 of the medium-voltage transistor area sequentially by dry etching, so as to form a medium-voltage area silicon recess 108 on the top of the silicon substrate 100 of the medium-voltage transistor area;
S6. as shown in FIG. 7, removing the first layer of photoresist 107 remaining on the surface of the whole wafer, and removing residual byproducts (polymer) by wet cleaning;
S7. as shown in FIG. 8, growing a medium-voltage gate oxide layer 109 on the surface of the whole wafer;
S8. coating a second layer of photoresist 110 to the surface of the whole wafer;
S9. as shown in FIG. 9, developing only the second layer of photoresist 110 of the high-voltage transistor area and the low-voltage transistor area, retaining the second layer of photoresist 110 of the medium-voltage transistor area, and protecting the medium-voltage transistor area with the second layer of photoresist 110;
S10. as shown in FIG. 10, removing the medium-voltage gate oxide layer 109 of the high-voltage transistor area and the low-voltage transistor area by dry etching, and stop on the hard mask layer 106;
S11. as shown in FIG. 11, removing the remaining second layer of photoresist 110;
S12. as shown in FIG. 12, removing the hard mask layer 106 of the high-voltage transistor area and the low-voltage transistor area by wet etching, completing the preparation of the medium-voltage gate oxide layer of the medium-voltage device; and
S13. performing a subsequent process to fabricate an integrated structure of transistors with different operating voltages.

According to the fabrication method for the integrated structure of transistors with different operating voltages of the embodiment 1, in the process of growing the medium-voltage gate oxide layer, only the photoresist is removed and the hard mask layer is retained after the hard mask layer 106 and the top of the silicone substrate 100 of the medium-voltage transistor area is removed by etching to form the medium-voltage area silicone recess (Si-Recess) 108, and then the medium-voltage gate oxide layer is grown; and then a layer of photoresist is coated to the surface of the wafer, and the high-voltage transistor area and the low-voltage transistor area are opened to remove the medium-voltage gate oxide layer 109 by dry etching and then remove the hard mask layer by wet etching, completing the preparation of the medium-voltage gate oxide layer of the medium-voltage device. In such a fabrication method for the integrated structure of the transistors with different operating voltages, before the medium-voltage gate oxide layer is grown, the high-voltage transistor area and the low-voltage transistor area are protected by the retained hard mask layer, so as to avoid additional growth of the gate oxide layer above the active area of the high-voltage transistor area and the low-voltage transistor area, thereby avoiding the deterioration of the step height of the low-voltage transistor area due to the subsequent use of the large amount of acid to remove the gate oxide layer (for example, a silicon dioxide film layer) additionally grown above the active area of the low-voltage transistor area, and preventing the electrical property and the reliability of the low-voltage device from being subsequently influenced while avoiding the influence of etching with the large amount of acid on the thickness of a high-voltage gate oxide layer which has already been grown, which is conducive to reducing the fluctuation in the process and enhancing the ability to accurately control the process. The fabrication method is simple and controllable, compatible with an existing process, and suitable for mass production.

### Embodiment 2

In a fabrication method for the integrated structure of the transistors with different operating voltages of the embodiment 1, in the step S3, the hard mask layer 106 is a SIN layer, and a surface of the SIN layer is oxidized by means of thermal oxygen, and thus a thin oxide layer is generated on the surface of the SIN layer, which avoids direct contact of the subsequentially coated photoresist with the SIN layer, resulting in nitrogen poisoning of the photoresist and affecting the photolithography accuracy.

Preferably, the high-voltage transistor has an operating voltage of 20V to 35V (for example, 32V or 25V);
the medium-voltage transistor has an operating voltage of 6V to 10V (for example, 8V); and
the low-voltage transistor has an operating voltage of less than 1V (for example, 0.9V).

Preferably, the silicon substrate 100 of the high-voltage transistor area is provided with a high-voltage P-well (HVPW); and
the silicon substrate (100) of the medium-voltage transistor area is provided with a medium-voltage P-well (MVPW).

Preferably, an upper surface of the area shallow trench isolation 101 is higher than that of the silicon substrate 100 by 10 Å to 100 Å.

Preferably, the area shallow trench isolation 101 and the low-voltage shallow trench isolation 102 are silicon oxide; and
the high-voltage gate oxide layer 105 and the medium-voltage gate oxide layer 109 are silicon oxide.

Preferably, in the step S6, the first layer of photoresist 107 remaining on the surface of the whole wafer is removed by dry etching.

Preferably, in the step S1, a liner oxide layer 103 is formed on the upper surface of the silicon substrate 100 of the high-voltage transistor area, the medium-voltage transistor area and the low-voltage transistor area; and
in the step S5, only the photoresist of the medium-voltage transistor area is developed, and then the hard mask layer 106, the liner oxide layer 103 and a top of the silicon substrate 100 of the medium-voltage transistor area are sequentially removed by dry etching, so as to form a medium-voltage area silicon recess (Si-Recess) 108 on the top of the silicon substrate 100 of the medium-voltage transistor area.

### Embodiment 3

In a fabrication method for the integrated structure of the transistors with different operating voltages of the embodiment 2, in the step S12, the wet etching amount of a phosphoric acid solution is adjusted, and the hard mask layer 106 of the high-voltage transistor area and the low-voltage transistor area is removed by wet etching.

### Embodiment 4

In a fabrication method for the integrated structure of the transistors with different operating voltages of the embodiment 1, in the step S7, the medium-voltage gate oxide layer 109 is grown on the surface of the whole wafer in a manner of first an ISSG (In-Situ Steam Generation) process and then an HTO (High Temperature Oxidation) process.

Preferably, in the step S7, the ISSG (In-Situ Steam Generation) process has an oxide growth thickness of 40 Å to 120 Å, and the HTO (High Temperature Oxidation) process has an oxide growth thickness of 100 Å to 300 Å. Since surfaces of the high-voltage transistor area and the low-voltage transistor area are protected by the hard mask layer, gate oxide of the high-voltage transistor area and the low-voltage transistor area are only grown above the hard mask layer.

Preferably, the medium-voltage gate oxide layer 109 grown in the step S7 has a thickness of 100 Å to 350 Å.

Preferably, in the step S5, the formed medium-voltage area silicon recess (Si-Recess) 108 has a depth of 100 Å to 200 Å (for example, 150 Å) in the silicon substrate 100.

Preferably, in the step S2, a depth of a bottom of the high-pressure gate oxide layer 105 penetrating deeply in the silicon substrate 100 ranges from 400 Å to 600 Å (for example, 460 Å).

### Embodiment 5

Based on the embodiment 1, the fabrication method for the integrated structure of the transistors with different operating voltages described herein is an integrated process method capable of fabricating an integrated structure of a high-voltage MOS transistor, a medium-voltage MOS transistor and a low-voltage MOS transistor on a 28 HKMG (28nm high dielectric coefficient metal gate) process platform, which can effectively improve the compatibility of the high-speed performance of the LV (low-voltage) MOS transistor and the high reliability of the MV (medium-voltage) MOS transistor and the HV (high-voltage) MOS transistor fabricated on the same process platform in the same process, and can be used to fabricate a display driver chip of a high-reliability AMOLED (Active-matrix organic light-emitting diode).

The embodiments described above are only preferred embodiments of the present application and are not intended to limit the present application. The scope of protection of the present application shall include any modifications, equivalent substitutions, improvements, etc. made within the spirit and principles of the present application.

What is claimed is:

1. A fabrication method for an integrated structure of transistors with different operating voltages, the integrated structure has a high-voltage transistor, a medium-voltage transistor and a low-voltage transistor formed on the same silicon substrate, and the fabrication method for the integrated structure comprises the following steps:
S1: providing a semiconductor substrate, wherein the semiconductor substrate is a silicon substrate provided with a high-voltage transistor area, a medium-voltage transistor area and a low-voltage transistor area separated by an area shallow trench isolation; the high-voltage transistor area is provided with a high-voltage shallow trench isolation inside; the low-voltage transistor area is provided with a low-voltage shallow trench isolation inside; the high-voltage shallow trench isolation is flush or higher than an upper surface of the silicon substrate; and an operating voltage of the high-voltage transistor is greater than that of the medium-voltage transistor, and the operating voltage of the medium-voltage transistor is greater than that of the low-voltage transistor;
S2: forming a high-voltage gate oxide layer only in the high-voltage transistor area but not forming the high-voltage gate oxide layer in the low-voltage transistor area and the medium-voltage transistor area, wherein a lower portion of the high-voltage gate oxide layer penetrates deeply into the silicon substrate, and an upper surface of the high-voltage gate oxide layer is flush with that of the area shallow trench isolation;
S3: depositing a hard mask layer on a surface of a wafer;
S4: coating a first layer of photoresist on the surface of the hard mask layer;
S5: developing only the photoresist of the medium-voltage transistor area, and then removing the hard mask layer and a top of the silicon substrate of the medium-voltage transistor area sequentially by dry etching, so as to form a medium-voltage area silicon recess on the top of the silicon substrate of the medium-voltage transistor area;
S6: removing the first layer of photoresist remaining on the surface of the whole wafer, and removing residual byproducts by wet cleaning;
S7: growing a medium-voltage gate oxide layer on the surface of the whole wafer;
S8: coating a second layer of photoresist to the surface of the whole wafer;
S9: developing only the second layer of photoresist of the high-voltage transistor area and the low-voltage transistor area, retaining the second layer of photoresist of the medium-voltage transistor area, and protecting the medium-voltage transistor area with the second layer of photoresist;
S10: removing the medium-voltage gate oxide layer of the high-voltage transistor area and the low-voltage transistor area by dry etching, and stopping the dry etching on the hard mask layer;
S11: removing the remaining second layer of photoresist;
S12: removing the hard mask layer of the high-voltage transistor area and the low-voltage transistor area by wet etching to fabricate the medium-voltage gate oxide layer; and
S13: performing a subsequent process to fabricate the integrated structure of the transistors with the different operating voltages.

2. The fabrication method according to claim 1, wherein, in the step S3, the hard mask layer is a SIN layer, and a surface of the SIN layer is oxidized by means of thermal oxygen, and thus a thin oxide layer is generated on the surface of the SIN layer.

3. The fabrication method according to claim 2, wherein, in the step S12, the wet etching amount of a phosphoric acid solution is adjusted, and the hard mask layer of the high-voltage transistor area and the low-voltage transistor area is removed by wet etching.

4. The fabrication method according to claim 1, wherein the high-voltage transistor has an operating voltage of 20V to 35V, the medium-voltage transistor has an operating voltage of 6V to 10V, and the low-voltage transistor has an operating voltage of less than 1V.

5. The fabrication method according to claim 4, wherein the high-voltage transistor has an operating voltage of 32V or 25V, the medium-voltage transistor has an operating voltage of 8V, and the low-voltage transistor has an operating voltage of 0.9V.

6. The fabrication method according to claim 1, wherein the silicon substrate of the high-voltage transistor area is provided with a high-voltage P-well, and the silicon substrate of the medium-voltage transistor area is provided with a medium-voltage P-well.

7. The fabrication method according to claim 1, wherein an upper surface of the area shallow trench isolation is higher than that of the silicon substrate by 10 Å to 100 Å.

8. The fabrication method according to claim 1, wherein the area shallow trench isolation and the low-voltage shallow trench isolation are silicon oxide, and the high-voltage gate oxide layer and the medium-voltage gate oxide layer are silicon oxide.

9. The fabrication method according to claim 1, wherein, in the step S6, the first layer of photoresist remaining on the surface of the whole wafer is removed by dry etching.

10. The fabrication method according to claim 1, wherein, in the step S1, a liner oxide layer is formed on the upper surface of the silicon substrate of the high-voltage transistor area, the medium-voltage transistor area and the low-voltage transistor area; and, in the step S5, only the photoresist of the medium-voltage transistor area is developed, and then the hard mask layer, the liner oxide layer and a top of the silicon substrate of the medium-voltage transistor area are sequentially removed by dry etching, so as to form the medium-voltage area silicon recess on the top of the silicon substrate of the medium-voltage transistor area.

11. The fabrication method according to claim 1, wherein, in the step S7, the medium-voltage gate oxide layer is grown on the surface of the whole wafer in a manner of first an In-Situ Steam Generation (ISSG) process and then a High Temperature Oxidation (HTO) process.

12. The fabrication method according to claim 11, wherein, in the step S7, the ISSG process has an oxide growth thickness of 40 Å to 120 Å, and the HTO process has an oxide growth thickness of 100 Å to 300 Å.

13. The fabrication method according to claim 1, wherein the medium-voltage gate oxide layer grown in the step S7 has a thickness of 100 Å to 350 Å.

14. The fabrication method according to claim 1, wherein, in the step S5, the formed medium-voltage area silicon recess has a depth of 100 Å to 200 Å in the silicon substrate.

15. The fabrication method according to claim 1, wherein, in the step S2, a depth of a bottom of the high-voltage gate oxide layer penetrating deeply in the silicon substrate ranges from 400 Å to 600 Å.

16. The fabrication method according to claim 1, wherein the fabrication method is an integrated process method capable of fabricating an integrated structure of three MOS transistors, that is, a high-voltage MOS transistor, a medium-voltage MOS transistor and a low-voltage MOS transistor, on a 28 HKMG process platform.
